(19) United States
(12) Patent Application Publication
(10) Pub. No.: US 2024/0250075 A1
(43) Pub. Date: Jul. 25, 2024

(54) INTEGRATED POWER MODULE PACKAGE OPENING WITH EXPOSED COMPONENT

(71) Applicant: Texas Instruments Incorporated, Dallas, TX (US)

(72) Inventors: Makoto Shibuya, Sunnyvale, CA (US); Kwang-Soo Kim, Sunnyvale, CA (US)

(21) Appl. No.: 18/156,449

(22) Filed: Jan. 19, 2023

(51) Int. Cl. H01L 25/16; H01L 21/56; H01L 23/00; H01L 23/31; H01L 23/495; H01L 23/538

(52) U.S. Cl. CPC H01L 25/16; H01L 21/56; H01L 23/3121; H01L 23/49513; H01L 23/49562; H01L 23/5383; H01L 24/29; H01L 24/32; H01L 24/48; H01L 24/73; H01L 24/83; H01L 24/85; H01L 24/92; H01L 2224/291; H01L 2224/32245; H01L 2224/48175; H01L 2224/73265; H01L 2224/83815; H01L 2224/85; H01L 2224/92247

(57) ABSTRACT

An electronic device includes a semiconductor die attached to a substrate and coupled to a circuit of the electronic device, an electronic component coupled to the circuit, and a package structure that encloses the semiconductor die, the package structure having an opening that exposes a portion of the electronic component. A method includes attaching a semiconductor die to a substrate or a die attach pad, performing an electrical connection process that couples the semiconductor die to a circuit, forming a package structure that encloses the semiconductor die and having an opening that exposes a metal terminal attached to the substrate, and attaching an electronic component through the opening to the metal terminal.

### BACKGROUND

Packaged electronic devices may include multiple components and/or dies interconnected to form an electronic circuit. High power circuits for integrated power modules (IPMs) often include large capacitors and other passive components outside of switching transistor dies, with circuit connections made by bond wires. High current connections often require wedge bonding using thick aluminum bond wires, such as transistor source and drain terminal connections of a half bridge circuit. However, heavy aluminum wedge bonding requires additional spacing between terminal connection points and tall capacitors or other adjacent components and structures due to the size of the wedge bonding tools. This limits attempts to reduce power module sizes and increase power density while ensuring adequate clearance between a wire bonding tool and components. Device cost can also be reduced by using common platforms such as package substrates and molds for multiple products having different specifications and electronic components that are of different sizes. For example, a family of integrated power modules may have different bus capacitor sizes to accommodate different power ratings and/or switching frequencies, and taller or wider capacitors require larger spacing distances to accommodate aluminum wedge bond tools, and a common platform would need to be sized for the largest bus capacitors used in the device product family.

### SUMMARY

In one aspect, an electronic device includes a semiconductor die attached to a substrate and coupled to a circuit of the electronic device, an electronic component coupled to the circuit, and a package structure that encloses the semiconductor die, the package structure having an opening that exposes a portion of the electronic component.

In another aspect, a system includes a circuit board and an electronic device attached to the circuit board. The electronic device includes a semiconductor die attached to a substrate and coupled to a circuit of the electronic device, an electronic component coupled to the circuit, a package structure that encloses the semiconductor die, the package structure having an opening that exposes a portion of the electronic component, and a conductive lead that is coupled to the circuit and extends outward from the package structure, where the conductive lead is coupled to the circuit board.

In a further aspect, a method includes attaching a semiconductor die to a substrate or a die attach pad, performing an electrical connection process that couples the semiconductor die to a circuit, forming a package structure that encloses the semiconductor die and having an opening that exposes a metal terminal attached to the substrate, and attaching an electronic component through the opening to the metal terminal.

### BRIEF DESCRIPTION OF THE DRAWINGS

FIG. 1 is a top perspective view of an electronic device having a package structure with an opening that exposes portions of passive components.

FIG. 1A is a sectional side elevation view taken along line 11A-1A of FIG. 1.

FIG. 1B is a top perspective view of the electronic device of FIG. 1 showing further details of internal components and interconnections.

FIG. 1C is a schematic diagram of a power conversion system including the electronic device of FIGS. 1-1B

FIG. 1D is a partial sectional side elevation view of a system including an implementation of the electronic device installed on a printed circuit board (PCB).

FIG. 1E is a partial sectional side elevation view of another system including another implementation of the electronic device installed on a PCB.

FIG. 2 is a flow diagram of a method of making an electronic device.

FIGS. 3-11 are partial sectional side elevation views of the electronic device of FIGS. 1-1C undergoing fabrication processing according to the method of FIG. 1.

FIG. 12 is a partial sectional side elevation view of another implementation of the electronic device.

FIG. 13 is a partial sectional side elevation view of another implementation of the electronic device.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value.

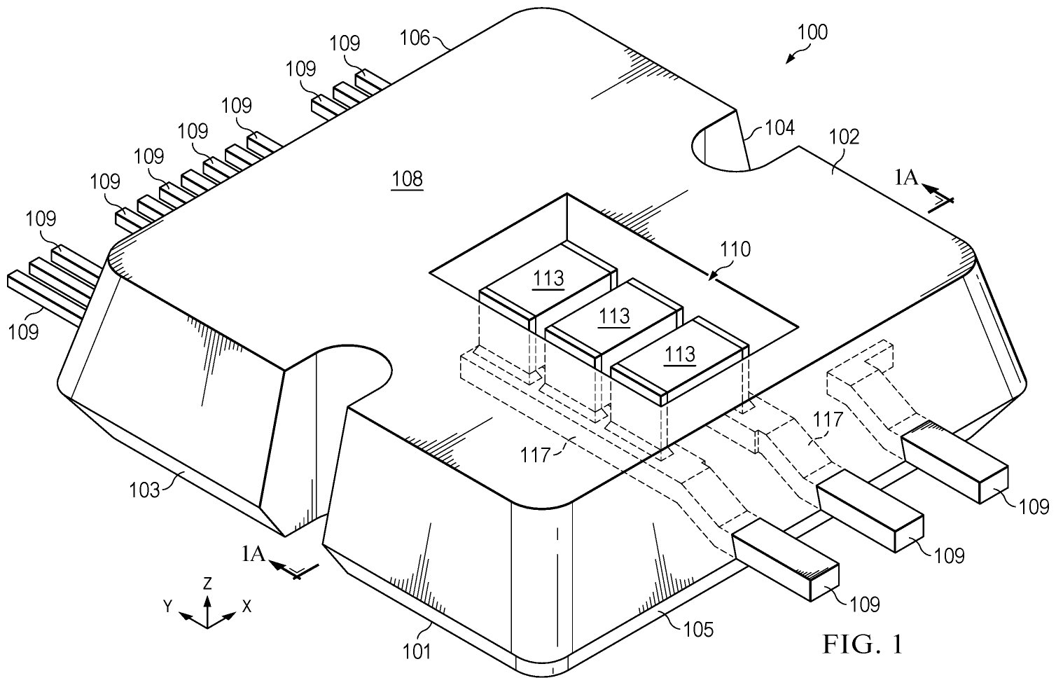

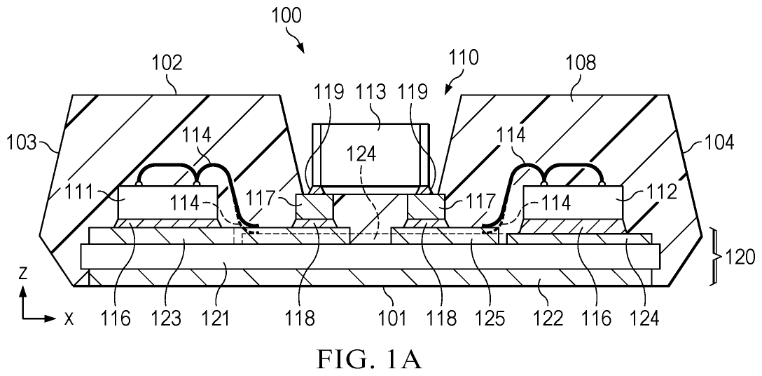

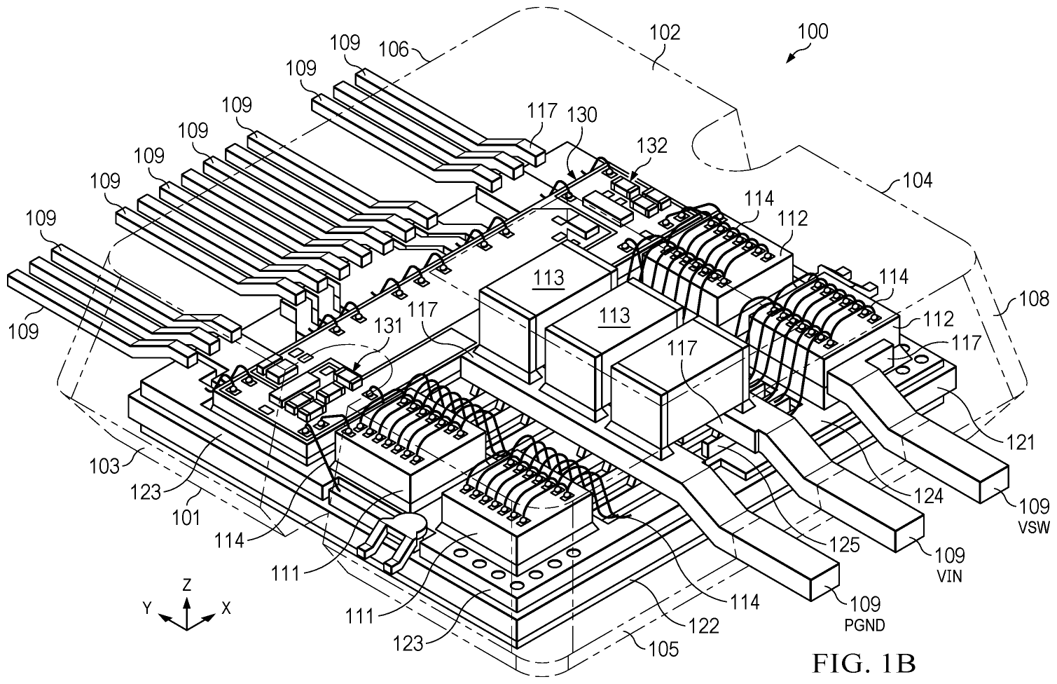

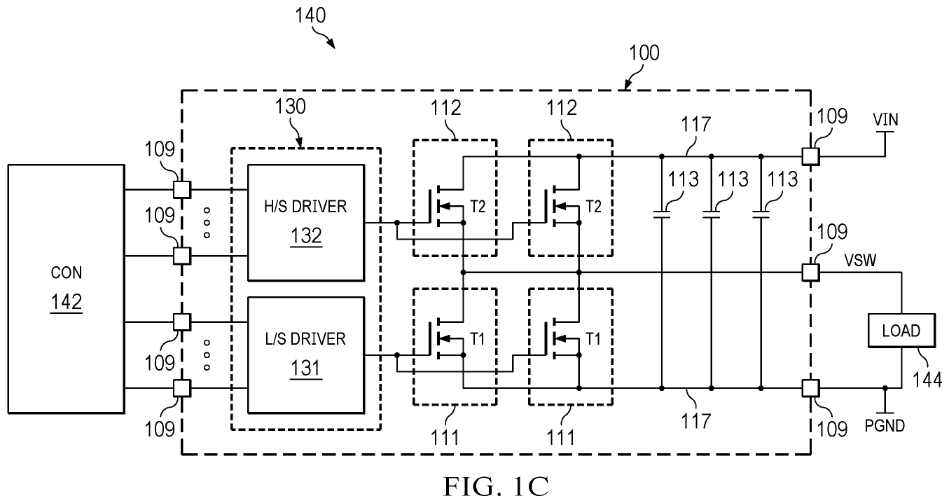

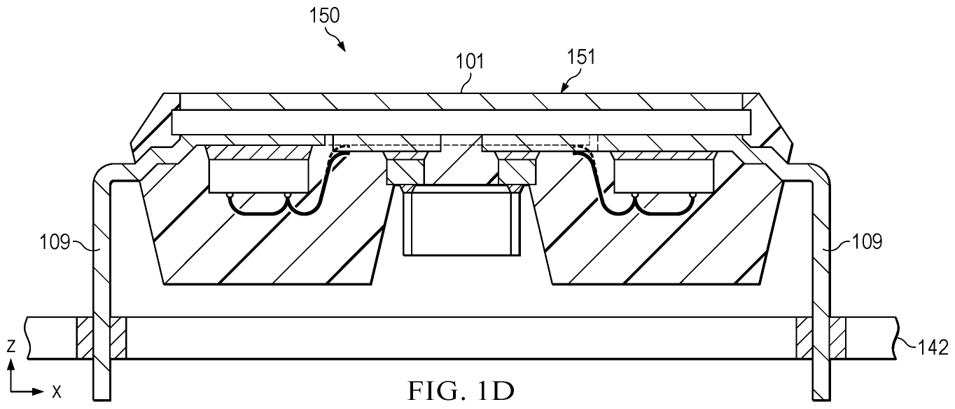

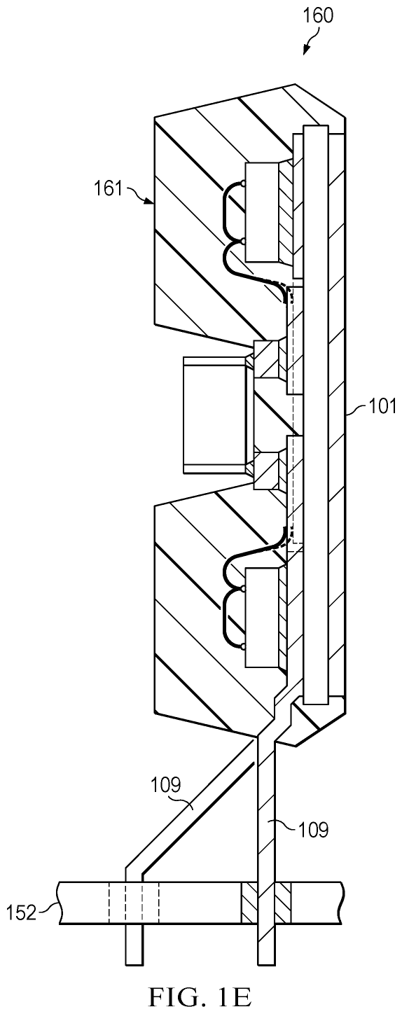

FIGS. 1-1B show an electronic device 100 with electronic components exposed through an opening in a package structure that facilitates package size reduction and increased power density while allowing the use of tall and/or wide electronic components to support multiple device specifications using a shared platform and use of aluminum wedge bond tools or other manufacturing equipment to support high power applications. FIG. 1 shows a top perspective view of the electronic device 100, FIG. 1A shows a sectional side elevation view of the electronic device 100, and FIG. 1B shows a partial cutaway top perspective view with further details of internal components and interconnections of the electronic device 100. The electronic device 100 is shown in FIGS. 1-1B in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another. As best shown in FIG. 1, the electronic device 100 has opposite first and second (e.g., bottom and top) sides 101 and 102, respectively, which are spaced apart from one another along the third direction Z. The electronic device 100 has laterally opposite third and fourth sides 103 and 104 spaced apart from one another along the first direction X, and opposite fifth and sixth sides 105 and 106 spaced apart from one another along the second direction Y in the illustrated orientation. The sides 101-106 in one example have substantially planar outer surfaces with the lateral sides 103-106 tapered from a mold parting line to facilitate mold separation during packaging. In other examples, one or more of the sides 101-106 have curves, angled features, or other non-planar surface features.

The electronic device 100 is a system in package (SIP) having a package structure 108, such as a molded plastic or ceramic structure, with conductive metal leads 109 (e.g., copper, aluminum, silver, gold, etc.) that are coupled to a circuit of the electronic device 100 and extend outward from the package structure 108. In one example, the electronic device 100 is a surface mount technology (SMT) integrated circuit with gull wing, J or other types of leads 109 configured to be soldered to corresponding conductive pads of a host PCB (not shown) with the bottom or first side 101 substantially parallel to the PCB surface. In other examples, the electronic device 100 has a through hole package form with two rows of through hole leads 109 partially exposed outside the package structure 108 to form a dual inline package (DIP) package type that can be soldered to a host PCB with the bottom or first side 101 substantially parallel to the PCB surface (e.g., FIG. 1D below) or with the first side 101 approximately perpendicular to the PCB surface (e.g., FIG. 1E below). Different package forms and types can be used in other examples, including without limitation no-lead packages, solder balls or bumps, conductive metal pillars and/or other conductive metal terminals for flip chip or ball grid array (BGA) type attachment to a host PCB or the like.

The package structure 108 includes an opening 110 (FIGS. 1 and 1A) that extends into a portion of the top or second side 102 of the electronic device. The electronic device 100 includes respective first and second semiconductor dies 111 and 112 (FIGS. 1A and 1B) as well as surface mount capacitor electronic components 113. The opening 110 exposes a portion of the electronic component 113 and facilitates installation of the electronic components 113 after formation of the package structure 108, and the package structure 108 encloses the semiconductor dies 111 and 112. The semiconductor dies 111 and 112 and the electronic components 113 are coupled by bond wires 114 (FIGS. 1A and 1B) and substrate routing connections to the circuit of the electronic device 100. As shown in FIGS. 1 and 1A, the electronic components 113 are exposed through the opening 110 of the package structure 108 and the package structure 108 encloses the bond wires 114 as shown in FIGS. 1A and 1B.

The illustrated example uses exposed surface mount bus capacitors soldered to bus bars or other metal terminals 117 after molding processing that provides the opening 110 with tapered sidewalls in the molded package structure 108. In other example, the package structure 108 can include two or more openings (not shown) that expose further respective electronic components. The opening 110 provides access to allow solder dispensing, automated pick and place attachment of the bus capacitor electronic components 113 and subsequent solder reflow to couple the capacitors 113 to transistors of a half bridge power converter circuit of the electronic device 100. The example electronic device 100 provides a manufacturing solution to facilitate space saving while providing current carrying capability via wedge bonding bond wire interconnections 114. This facilitates device size reduction to support compact power systems or other end use applications.

As best shown in FIG. 1A, the semiconductor dies 111 and 112 are attached to a substrate 120 by solder connections 116, and the metal terminals 117 are attached to the substrate 120 by solder connections 118. In another example, the semiconductor dies 111 and 112 can be attached to the substrate 120 by an adhesive (not shown). The package structure 108 encloses the semiconductor dies 111 and 112 as well as the bond wires 114. The package structure 108 in this example also encloses upper and side portions of the substrate 120 and the bottom side of the substrate 120 extends along the first side 101 (bottom side) of the electronic device 100. The electronic components 113 are coupled to the metal terminals 117 by solder connections 119. In the illustrated example, the substrate 120 is a direct bonded copper (DBC) substrate with a ceramic substrate base 121 (e.g., Al₂O₃ or AlN) and patterned copper foil traces bonded to respective opposite (e.g., bottom and top) sides of the substrate base 121. The illustrated example includes bottom side copper trace feature 122 along the first side 101, as well as top side patterned interleaved copper finger trace structures 123, 124 and 125. In another example, a different substrate type and/or die attach pad structure can be used to support the metal terminals 117 and/or the semiconductor dies 111 and 112.

As further shown in FIG. 1B, the electronic device 100 in one example includes a control board 130 attached to the substrate 120. The illustrated electronic device 100 is an integrated power module (IPM) with a half bridge transistor circuit including transistors of the semiconductor dies 111 and 112, transistor gate driver circuitry of the control board 130 and with three exposed bus capacitors 113. The control board 130 in one example includes a substrate with routing connections, such as patterned conductive metal traces and vias, as well as electronic components (e.g., further semiconductor dies, passive components, etc.) that provide on-board driver circuitry including a first driver circuit 131 that controls operation of one or more low side transistors of the half bridge circuit, and a second driver circuit 132 that controls operation of one or more high side transistors of the half bridge circuit of the electronic device 100. The example electronic device includes two instances of the first semiconductor die 111 having respective parallel connected low side transistors, as well as two instances of the second semiconductor die 112 having respective parallel connected high side transistors. The semiconductor dies 111 and 112 are attached to the substrate 120 and transistors of the dies 111 and 112 are coupled by associated bond wires 114 to the half bridge circuit. The bus capacitor electronic components 113 are coupled to the circuit via first and second busbar metal terminals 117.

Referring also to FIGS. 1C-1E, FIG. 1C shows a schematic diagram of a power conversion system 140 including the electronic device 100, FIG. 1D shows a partial side elevation view of a system 150 including an implementation of the electronic device installed on a PCB, and FIG. 1E shows a partial side view of another system 160 including another implementation of the electronic device installed on a PCB. In the example of FIGS. 1B and 1C, the electronic device 100 has first, second and third conductive leads 109 respectively coupled to a reference node (labelled PGND in FIG. 1B), a switching node (labelled VSW) and an input node (labelled VIN). The electronic device 100 has first and second metal terminals 117 respectively coupled to the reference node PGND and the input node VIN. The instances of the first semiconductor die 111 each have a first transistor T1 with a drain coupled to the switching node VSW and a source coupled to the first metal terminal 117. The instances of the second semiconductor die 112 each have a second transistor T2 with a drain coupled to the second metal terminal 117 and a source coupled to the switching node. In one example, the instances of the first transistor T1 and the second transistor T2 are gallium nitride GaN transistors. In other examples, different transistors and types can be used, including without limitation silicon-based transistors such as FETs, bipolar transistors, IGBTs, etc. The first conductive lead 109 is coupled to the first metal terminal 117 to form the reference node PGND, the second conductive lead 109 is coupled to the switching node VSW, and the third conductive lead 109 is coupled to the second metal terminal 117 to form the input node VIN of the half bridge circuit. The first driver circuit 131 is operatively coupled to a gate of the instances of the first transistor T1, and the second driver circuit 132 is operatively coupled to a gate of the instances of the second transistor T2.

In the example of FIGS. 1-1C, each instance of the bus capacitor electronic component 113 has a first terminal soldered to the first metal terminal 117 and a second terminal coupled to the second metal terminal 117. In the illustrated example, the first, second and third leads 109 coupled to the respective reference, switching and input nodes PGND, VSW, and VIN are contiguous metal structures with respective conductive metal terminals 117, for example, initially part of a starting lead frame panel array during fabrication of the electronic device. For example, the first conductive lead 109 and the first metal terminal 117 are a contiguous metal structure that forms the reference node PGND with solder connections to first terminals of the bus capacitor electronic components 117, and the third conductive lead 109 and the second metal terminal 117 are a contiguous metal structure that forms the input node VIN with solder connections to the second terminals of the bus capacitor electronic components 117. Interleaved finger structures 123, 124, and 125 (FIG. 1A) of the DBC substrate 120 and associated bond wires 114 provide interconnections of the transistor terminals to the respective reference, switching and input nodes PGND, VSW, and VIN to form the half bridge circuit arrangement illustrated in FIG. 1C.

The example system 140 in FIG. 1C includes an implementation of the electronic device 100 of FIGS. 1-1B, for example, mounted on a PCB (not shown) along with a controller 142 attached to the PCB. The controller 142 has outputs coupled to respective ones of the first and second driver circuits 131 (low side driver and 132, for example, to provide switching and other control signals for controlled operation of the transistors T1 and T2 and other power converter circuitry of the electronic device to control power delivered to a load 144 of the system 140. In one example, the system 140 provides a switching DC to DC converter to drive the load 144 based on control signals from the controller 142.

FIG. 1D shows a system 150 that includes an electronic device 151 that is an implementation of the electronic device 100 described above, except that the electronic device 151 has a through hole package form with two rows of through hole leads 109 partially exposed outside the package structure. This example provides a dual inline package type that is soldered to plated through holes of a host PCB 152 with the bottom or first side 101 substantially parallel to the PCB surface. FIG. 1E shows another example system 160 with an electronic device 161 that is another implementation of the electronic device 100 described above, except that the electronic device 161 has another through hole package form with two rows of through hole leads 109 partially exposed and soldered to plated through holes of a host PCB 162, and the first side 101 of the electronic device is approximately perpendicular to the PCB surface.

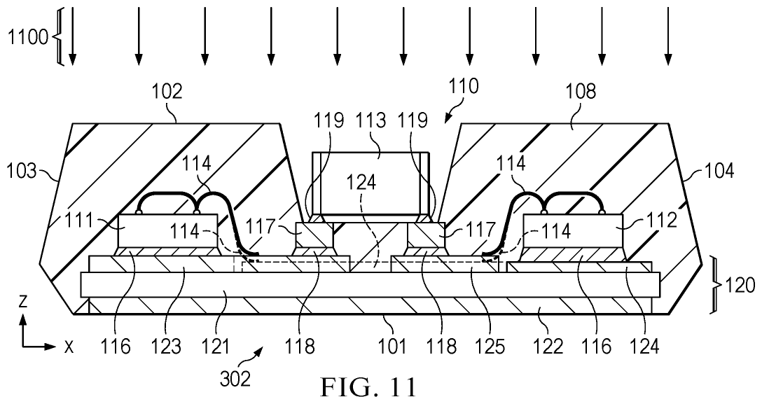

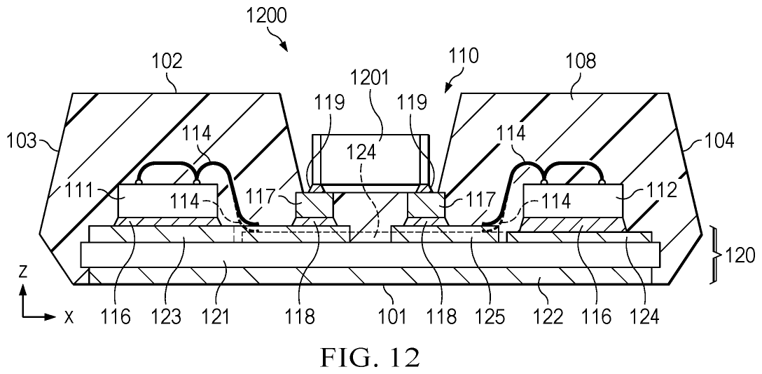

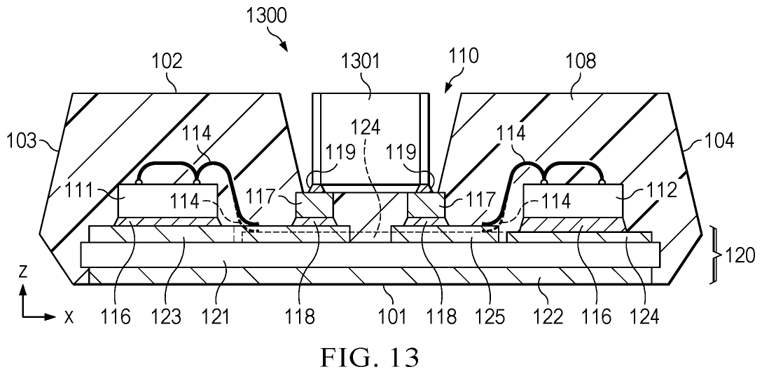

The example implementations of the electronic device 100 provide low manufacturing cost advantages by facilitating use of common platforms such as the package substrate 120 for multiple products having different specifications and electronic components. In one example, low power modules can use less than three of the exposed capacitor electronic components 113 and/or fewer than two instances of the respective semiconductor dies 111 and 112, while higher power devices of a product family can include more components 113 and/or instances of the semiconductor dies 111 and 112. In these or other examples, the sizing and location of the opening 110 and the bus bar metal terminals 117 can accommodate one or more electronic components 113 of different sizes, for example, to allow use of lower cost smaller components 113 for low power products (e.g., FIGS. 11 and 12 below) while larger electronic components 113 can be installed for higher power products (e.g., FIG. 13 below). In addition, the package structure opening 110 facilitates installation of the exposed electronic components 113 after wire bonding, and this helps efforts to reduce the package size while still allowing the use of high current wedge bond wire interconnections since the taller electronic components 113 do not present an obstruction to wedge bonding tooling during wire bonding operations. In this regard, a common platform for a family of products does not need to be sized for the largest bus capacitors used in the device product family. In addition, the provision of the opening 110 in the package structure can help improve heat dissipation for better thermal performance of the half bridge circuit during powered operation of the electronic device 100. An additional benefit is the ability to concurrently manufacture a large number of the electronic devices (or panel arrays thereof) with no installed bus capacitors, and later populate the suitably sized bus capacitor electronic components 113 based on a desired performance specification for device variants within a family of electronic device products.

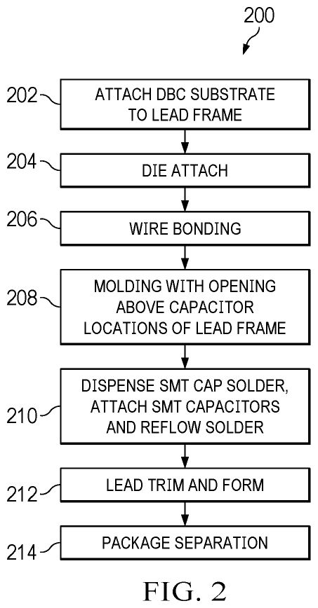

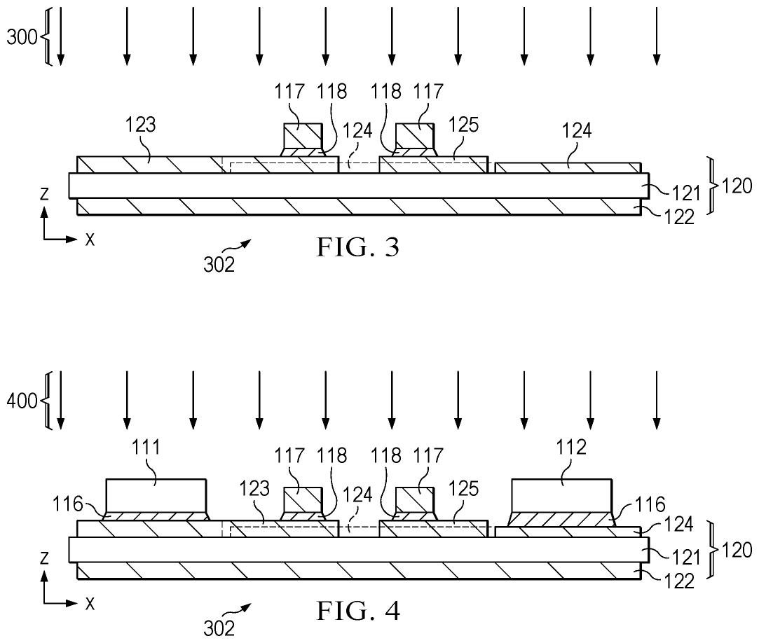

Referring also to FIGS. 2-11, FIG. 2 shows a method 200 of making an electronic device and FIGS. 3-11 show the example electronic device 100 of FIGS. 1-1C above undergoing fabrication processing according to the method 200. At 202 in FIG. 2, the method 200 includes attaching a substrate to a lead frame. FIG. 3 shows one example, in which a substrate attach process 300 is performed that attaches a substrate 120 to a lead frame having the metal terminals 117, leads, tie bars and other features (not shown) in each unit area of a starting lead frame panel array 302 with rows and columns of unit areas. In one example, the attachment process 300 includes soldering or brazing conductive features (e.g., the interleaved finger copper metal trace features 123-125) of the DBC substrate 120 to respective portions of the metal terminals 117 of the lead frame panel array 302. In the illustrated example, solder connections 118 electrically and mechanically connect the illustrated portions of the substrate 120 to the metal terminals 117 of the lead frame panel array 302. In another example, the substrate 120 can be attached to select features of the lead frame panel array 302 in each respective unit area using adhesive, with electrical connections being made to the metal terminals 117 and the substrate features 123-125 by bond wires as needed.

The method 200 continues at 204 in FIG. 2 with die and passive component attachment to the substrate 120. FIG. 4 shows one example, in which a die and component attach process 400 is performed that attaches the semiconductor dies 111 and 112 and passive components (e.g., of the driver circuits 131 and 132, not shown in FIG. 4) to respective metal trace features of the substrate 120. In one example, the semiconductor dies 111 and 112 are attached to respective die attach pad portions of the upper trace layer of the substrate 120 using conductive or nonconductive adhesive, and the attach process 400 includes a thermal and/or UV or other adhesive curing step. In the illustrated example, the die and passive component attach process 400 also includes applying (e.g., dispensing, silk-screening, etc.) solder paste (e.g., solder paste 116 in FIG. 4) on select portions of the illustrated conductive metal trace layer features 123 and 124 of the substrate 120 (as well as on locations corresponding to the components of the driver circuits 131 and 132), followed by automated pick and place attachment of the semiconductor dies 111, 112, and the components of the circuits 131 and 132 onto the respective solder paste at the corresponding locations on the top side of the substrate 120 in any suitable order, with a single thermal reflow process to reflow the solder paste and create conductive solder connections to the substrate 120. In another example, the semiconductor dies 111 and 112 (or one of them) can be attached to a separate die attach pad (not shown), such as a die attach pad feature of a starting lead frame panel array in each unit area thereof.

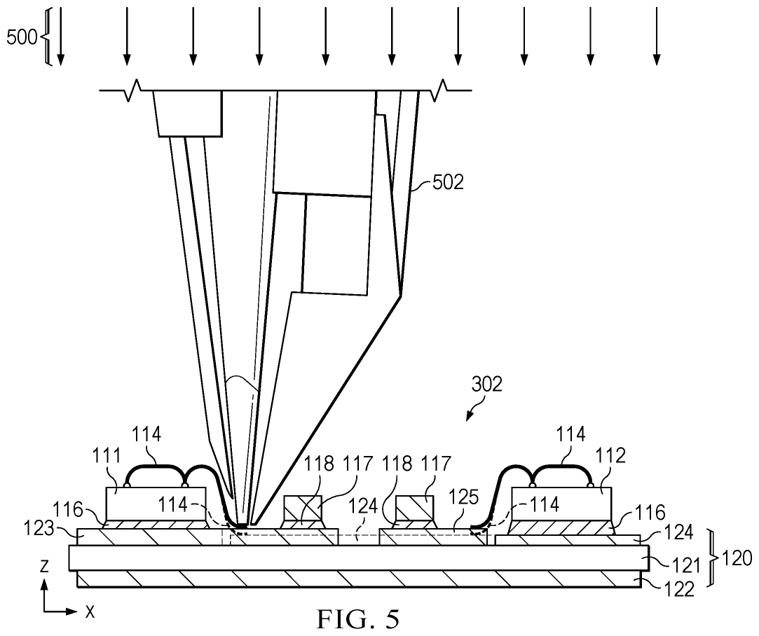

The method 200 continues at 206 in FIG. 2 with electrical connection processing by an electrical connection process 500 that couples the semiconductor dies 111 and 112 and other components to a circuit. FIG. 5 shows one example, in which a wire bonding electrical connection process 500 is performed that forms the bond wires 114 to provide electrical circuit connections for the transistors T1 and T2 and other circuitry of the integrated power module of the electronic device 100. The illustrated example in FIG. 5 shows a wedge bonding process 500 using a fairly large wedge bonding tool 502. As shown in FIG. 5, the absence of the bus capacitor electronic components 113 at this stage of the process 200 allows the device size to be reduced along the first direction X, whereas the X-direction spacing between the metal terminals 117 and the semiconductor dies 111 and 112 would need to be significantly increased to provide adequate clearance for the wedge bonding tool 502 if the bus capacitor electronic components 113 were installed before wire bonding.

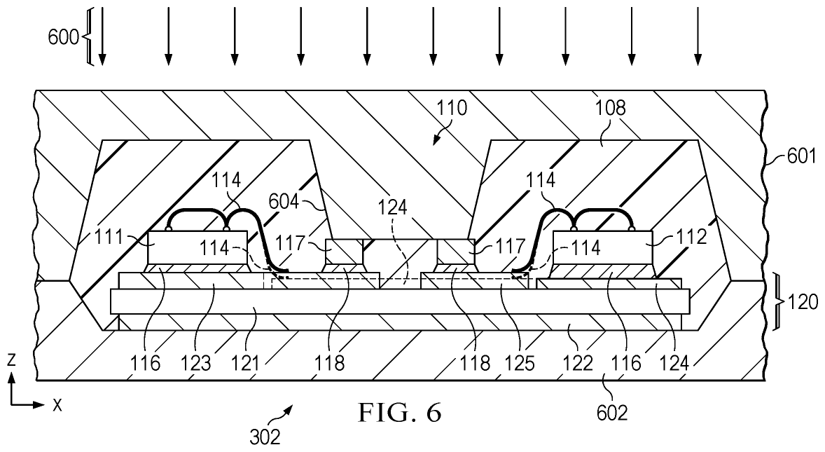

In the illustrated example, the method 200 then continues with molding at 208, followed by attachment of the bus capacitor electronic components at 210. In one implementation, the molding processing at 208 includes forming a package structure (e.g., package structure 108 above) that encloses the semiconductor dies 111 and 112 and has an opening (e.g., opening 110) that exposes prospective locations of the electronic components 113, such as portions of the metal terminals 117 attached to the substrate 120. FIG. 6 shows one example of the molding processing at 208, in which a molding process 600 is performed using a mold having an upper first portion 601 and a lower second portion 602. The mold portions 601 and 602 are shown in a closed position in FIG. 6. The first mold portion 601 in this example includes a mold indent feature 604 that engages a surface of the metal terminals 117 to create the opening 110 of the package structure 108 that exposes the engaged surfaces of the metal terminals 117 in each unit area of the lead frame panel array 302. To facilitate mold opening after injection and cooling of the mold material, the indent feature 604 has tapered or angled sidewalls and the resulting opening 110 has tapered sidewalls (e.g., as shown in FIGS. 1 and 1A above). In another implementation, the mold portion 601 does not have the indent feature 604 and the molding process 600 does not form the opening 110, and instead the opening 110 is created after molding using a suitable material removal process, such as laser ablation (not shown).

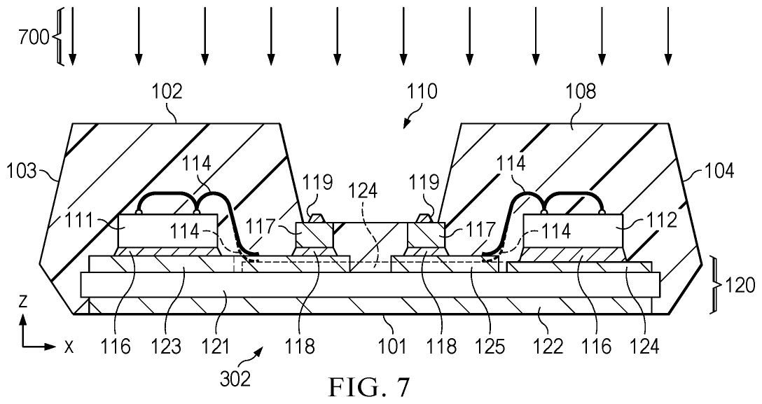

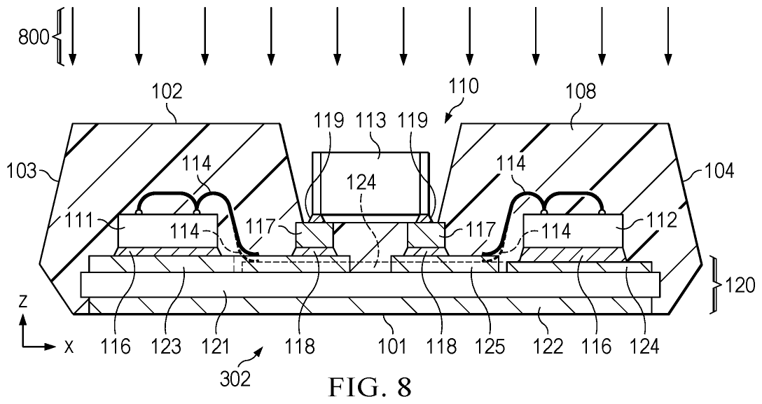

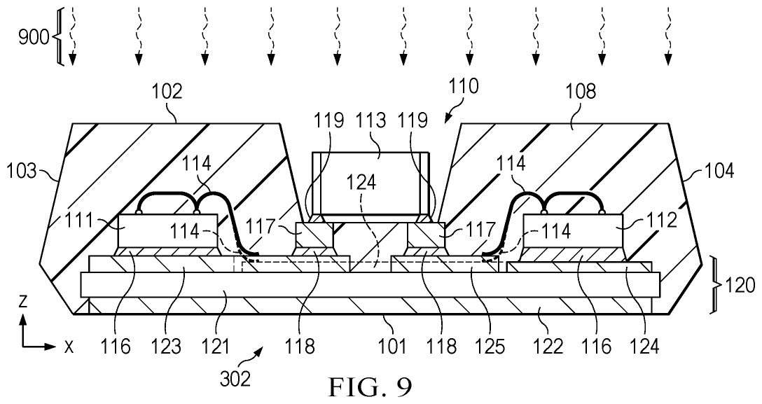

A 210 in FIG. 2, the method 200 includes attaching one or more of the electronic components 113 through the respective opening 110 to the associated metal terminals 117 in each unit area of the lead frame panel array 302. FIGS. 7-9 show one example of the processing at 210 that includes soldering the terminals of each instance of the electronic component 113 to the respective corresponding portions of the metal terminals 117 to couple the electronic components 113 to the circuit of the prospective electronic device in each unit area of the lead frame panel array 302. In one implementation, a dispensing process 700 is performed in FIG. 7 (e.g., dispensing, printing, silk screening, etc.) that dispenses the solder paste 119 on the metal terminals 117. FIG. 8 shows performance of an automated pick and place attachment process 800 that attaches one or more instances of the electronic component 113 through the opening 110 and on the dispensed solder paste 119 in each unit area of the lead frame panel array 302. FIG. 9 shows a subsequent thermal reflow process 900 that reflows the solder paste and creates conductive solder connections 119 to the metal terminals 117 to couple the electronic components 113 to the circuit in each unit area of the lead frame panel array 302.

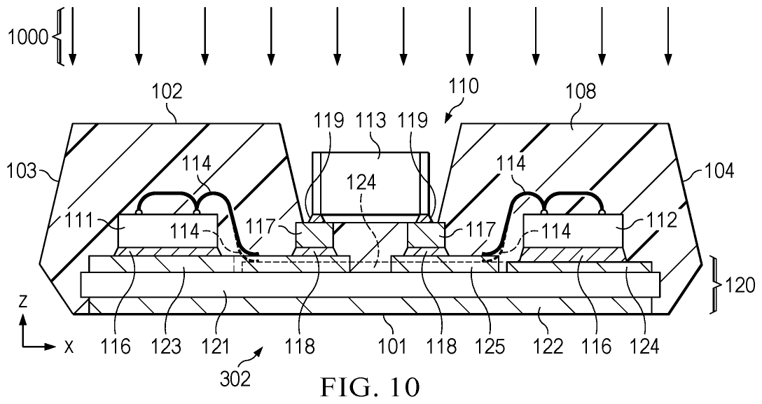

The method 200 in one example also includes lead trimming and/or forming operations at 212 in FIG. 2. FIG. 10 shows one example, in which a lead forming process 1000 is performed (e.g., using forming equipment, not shown) that trims and selectively bends exposed portions of some of the conductive metal leads 109 to form suitable leads of any suitable shape (e.g., j or gullwing leads 109 as shown in FIG. 1 above, through hole leads in a DIP package form (e.g., FIGS. 1D and 1E above), etc. The method 200 in one example also includes package separation at 214 in FIG. 2. FIG. 11 shows one example, in which a package separation process 1100 is performed that separates individual instances of the packaged electronic device 100 from the starting array.

FIG. 12 shows another implementation 1200 of the above described electronic device, including the features and components as described above. In the electronic device 1200, one or more smaller electronic components 1201 are soldered by solder connections 119 to the exposed metal terminals 117, for example, for a low power device in a family of integrated power module devices. FIG. 13 shows another implementation 1300 of the electronic device described above, in which one or more taller and wider electronic components 1301 are soldered by the solder connections 119 to the exposed metal terminals 117 through the opening 110 in the molded package structure 108, such as for a higher power device 1300 in the family of integrated power module devices. For the example electronic device 100, 1200 and 1300 having half bridge circuits for integrated power module products, the decoupling or bus capacitor can be the tallest component, for example, approximately 10 times taller compared with the semiconductor does 111 and 112 and other passive components (e.g., of the driver circuits 131 and 132). The provision of the opening 110 allows the potentially large capacitors 113 to be installed after wire bonding to help reduce the overall package size and increase power density for a wide variety of device maximum input voltage and switching frequency ratings, while using common components and platforms for a family of different electronic device products. Attaching passive components 113 (e.g., bus capacitors) after wire bonding and molding provides additional clearance for stitch or wedge bonding tools and allows use of a single layout for multiple voltage rating devices, and the opening 110 in molded package structure 108 exposes the passive components 113 and can facilitate heat removal in operation.

Modifications are possible in the described examples, and other implementations are possible, within the scope of the claims.

What is claimed is:

1. An electronic device, comprising:
a semiconductor die attached to a substrate and coupled to a circuit of the electronic device;
an electronic component coupled to the circuit; and
a package structure that encloses the semiconductor die, the package structure having an opening that exposes a portion of the electronic component.

2. The electronic device of claim 1, further comprising:
a conductive lead that is coupled to the circuit and extends outward from the package structure; and
a metal terminal attached to the substrate, the electronic component being coupled to the metal terminal.

3. The electronic device of claim 2, wherein:
the metal terminal is coupled to the conductive lead; and
the electronic component is soldered to the metal terminal.

4. The electronic device of claim 1, wherein:
the electronic device includes a second semiconductor die, first, second, and third conductive leads, and first and second metal terminals;
the semiconductor die is a first semiconductor die attached to the substrate and having a first transistor with a drain coupled to a switching node of the circuit and a source coupled to the first metal terminal;
the second semiconductor die is attached to the substrate and has a second transistor with a drain coupled to the second metal terminal and a source coupled to the switching node;
the first conductive lead is coupled to the first metal terminal to form a reference node of the circuit;
the second conductive lead is coupled to the switching node of the circuit; and
the third conductive lead is coupled to the second metal terminal to form an input node of the circuit.

5. The electronic device of claim 4, further comprising a control board attached to the substrate and having a first driver circuit coupled to a gate of the first transistor, and a second driver circuit coupled to a gate of the second transistor.

6. The electronic device of claim 4, wherein the electronic component is a capacitor having a first terminal soldered to the first metal terminal and a second terminal coupled to the second metal terminal.

7. The electronic device of claim 6, comprising a second capacitor exposed in the opening of the package structure and having a first terminal soldered to the first metal terminal and a second terminal coupled to the second metal terminal.

8. The electronic device of claim 1, wherein the electronic component is a passive circuit component.

9. The electronic device of claim 8, wherein the electronic component has terminals soldered to respective metal terminals of the electronic device.

10. A system, comprising:
a circuit board; and
an electronic device attached to the circuit board, the electronic device comprising: a semiconductor die attached to a substrate and coupled to a circuit of the electronic device; an electronic component coupled to the circuit; a package structure that encloses the semiconductor die, the package structure having an opening that exposes a portion of the electronic component; and a conductive lead that is coupled to the circuit and extends outward from the package structure, the conductive lead coupled to the circuit board.

11. The system of claim 10, wherein the electronic device further comprises: a conductive lead that is coupled to the circuit and extends outward from the package structure; and a metal terminal attached to the substrate, the electronic component being coupled to the metal terminal.

12. The system of claim 10, wherein:
the electronic device includes a second semiconductor die, first, second, and third conductive leads, and first and second metal terminals;
the semiconductor die is a first semiconductor die attached to the substrate and having a first transistor with a drain coupled to a switching node of the circuit and a source coupled to the first metal terminal;
the second semiconductor die is attached to the substrate and has a second transistor with a drain coupled to the second metal terminal and a source coupled to the switching node;
the first conductive lead is coupled to the first metal terminal to form a reference node of the circuit;
the second conductive lead is coupled to the switching node of the circuit; and
the third conductive lead is coupled to the second metal terminal to form an input node of the circuit.

13. The system of claim 12, wherein the electronic device further comprises a control board attached to the substrate and having a first driver circuit coupled to a gate of the first transistor, and a second driver circuit coupled to a gate of the second transistor.

14. The system of claim 13, further comprising a controller attached to the circuit board and having outputs coupled to respective ones of the first and second driver circuits.

15. A method of fabricating an electronic device, the method comprising:
attaching a semiconductor die to a substrate or a die attach pad;
performing an electrical connection process that couples the semiconductor die to a circuit;
forming a package structure that encloses the semiconductor die and having an opening that exposes a metal terminal attached to the substrate; and
attaching an electronic component through the opening to the metal terminal.

16. The method of claim 15, wherein forming the package structure includes performing a molding process with a mold feature engaging a surface of the metal terminal to create the opening of the package structure.

17. The method of claim 16, wherein attaching the electronic component includes soldering a terminal of the electronic component to the metal terminal to couple the electronic component to the circuit.

18. The method of claim 16, wherein attaching the electronic component includes:
dispensing solder paste on the metal terminal;
attaching a terminal of the electronic component on the solder paste; and
reflowing the solder paste to couple the electronic component to the circuit.

19. The method of claim 15, wherein attaching the electronic component includes soldering a terminal of the electronic component to the metal terminal to couple the electronic component to the circuit.

20. The method of claim 19, wherein attaching the electronic component includes:
dispensing solder paste on the metal terminal;
attaching a terminal of the electronic component on the solder paste; and
reflowing the solder paste to couple the electronic component to the circuit.
